(19) United States
(12) Patent Application Publication
(10) Pub. No.: US 2025/0138429 A1
(43) Pub. Date: May 1, 2025

(54) ENDPOINT DETECTION IN DRY DEVELOPMENT OF PHOTORESIST

(71) Applicant: Tokyo Electron Limited, Tokyo (JP)

(72) Inventors: Qi WANG, Albany, NY (US); Steven GRZESKOWIAK, Albany, NY (US); Nicholas SMIESZEK, Albany, NY (US); Blaze MESSER, Albany, NY (US); Sergey VORONIN, Albany, NY (US); Akiteru KO, Albany, NY (US); Eric Chih-Fang LIU, Albany, NY (US); Ashawaraya SHALINI, Fremont, CA (US); Da SONG, Albany, NY (US)

(73) Assignee: Tokyo Electron Limited, Tokyo (JP)

(21) Appl. No.: 18/498,698

(22) Filed: Oct. 31, 2023

(51) Int. Cl. G03F 7/36; G03F 7/004; H01L 21/66

(52) U.S. Cl. CPC G03F 7/36; H01L 22/26; G03F 7/0042

(57) ABSTRACT

A method of endpoint detection includes performing a surface treatment on a wafer without plasma in a process chamber which includes an outlet configured to output an exhaust gas of the surface treatment. An exhaust plasma is generated from the exhaust gas in a plasma coupler. The exhaust plasma is analyzed to determine an endpoint of the surface treatment. A system includes a process chamber configured to receive a wafer and perform a surface treatment on the wafer without plasma. The process chamber includes an outlet configured to output an exhaust gas of the surface treatment. A plasma coupler is configured to receive the exhaust gas and generate an exhaust plasma therefrom. A detector is configured to receive and analyze the exhaust plasma.

### FIELD OF THE INVENTION

This disclosure relates generally to semiconductor processing and more specifically to endpoint detection.

### BACKGROUND

Device formation within microelectronic workpieces typically involves a series of manufacturing techniques related to the formation, patterning and removal of a number of layers of materials on a substrate. To meet the physical and electrical specifications of current and next generation semiconductor devices, process flows are being developed to reduce feature size while maintaining structure integrity for various patterning processes. Particularly, plasma processing plays a vital role in the deposition and removal of materials in the production of semiconductor devices. Typical examples include plasma-assisted chemical vapor deposition, plasma-assisted physical vapor deposition, plasma etching, plasma-less etching, radical assisted etching, plasma cleaning, etc. Many characterization techniques have therefore been developed for various processes.

### SUMMARY

The present disclosure relates to a method of endpoint detection and a system for endpoint detection.

According to a first aspect of the disclosure, a method of endpoint detection is provided. The method includes performing a surface treatment on a wafer without plasma or with a remote plasma in a process chamber which includes an outlet configured to output an exhaust gas of the surface treatment. An exhaust plasma is generated from the exhaust gas in a plasma coupler. The exhaust plasma is analyzed to determine an endpoint of the surface treatment.

In some embodiments, performing the surface treatment includes executing a dry development process, without plasma, of a metal oxide resist formed on the wafer.

In some embodiments, analyzing the exhaust plasma includes detecting a byproduct of the surface treatment using optical emission spectroscopy.

In some embodiments, the method further includes providing a recipe for the surface treatment EPD. The process gas includes reactive precursor gas species and carrier gases. The process gas is introduced into the process chamber initially at an overall flow rate that is 1.5 to 100 times of an overall flow rate of the recipe while keeping flow rate ratios of the gas species the same as the recipe.

In some embodiments, the method further includes increasing pressure in the process chamber while introducing the process gas into the process chamber at faster flow rates. After the pressure in the process chamber approaches the pressure set in the recipe, the overall flow rate is gradually reduced to the overall flow rate of the recipe.

In some embodiments, the method further includes increasing the pressure in the process chamber to the recipe pressure. The pressure is maintained at the recipe pressure so that the surface treatment is performed according to the recipe.

In some embodiments, the method further includes loading the wafer into the process chamber under vacuum before initially introducing the process gas into the process chamber.

In some embodiments, the method further includes introducing the process gas initially into the process chamber using a first flow control system. After the pressure in the process chamber approaches the recipe pressure, the process gas is introduced into the process chamber using a second flow control system. The first flow control system has a higher conductivity than the second flow control system.

In some embodiments, the overall flow rate is gradually reduced to the overall flow rate of the recipe after the pressure approaches the recipe pressure.

In some embodiments, the overall flow rate is initially 2 to 100 times of the overall flow rate of the recipe.

In some embodiments, performing the surface treatment includes executing a dry development process, without plasma or with a remote plasma, of a metal oxide resist formed on the wafer. Analyzing the exhaust plasma includes monitoring a byproduct of the dry development process by monitoring at least one target wavelength signal using optical emission spectroscopy.

In some embodiments, the method further includes recording a first time when the at least one target wavelength signal exceeds a first threshold corresponding to an onset of the surface treatment. A second time is recorded when at least one the target wavelength signal falls below a second threshold corresponding to an end of the surface treatment.

In some embodiments, the method further includes determining an over-etch time of the dry development process based on the first time and the second time.

In some embodiments, the method further includes determining a duration of the dry development process based on the first time and the second time. In another embodiment, the endpoint is determined based on the first time alone. In yet another embodiment, the endpoint is determined based on the first time and the over-etch time.

According to a second aspect of the disclosure, a system for endpoint detection is provided. The method includes a process chamber configured to receive a wafer and perform a surface treatment on the wafer without plasma. The process chamber includes an outlet configured to output an exhaust gas of the surface treatment. A plasma coupler is configured to receive the exhaust gas and generate an exhaust plasma therefrom. A detector is configured to receive and analyze the exhaust plasma.

In some embodiments, the system further includes a turbo molecular pump configured to transfer the exhaust gas out of the outlet of the process chamber.

In some embodiments, the detector includes an optical emission spectrometer.

In some embodiments, the surface treatment includes a dry development of metal oxide resist.

In some embodiments, the method further includes a controller configured to determine an endpoint of the surface treatment based on analysis of the detector.

In some embodiments, the plasma coupler is located downstream relative to the process chamber. The detector is located outside the process chamber and downstream relative to the plasma coupler.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a system for endpoint detection in accordance with some embodiments of the present disclosure.

FIG. 1B shows a system for endpoint detection in accordance with some embodiments of the present disclosure.

FIG. 2 shows a flow chart of a process for endpoint detection in accordance with some embodiments of the present disclosure.

FIG. 3 shows a diagram of a process for endpoint detection in accordance with some embodiments of the present disclosure.

FIGS. 4A, 4B and 4C show byproduct detection in accordance with some embodiments of the present disclosure.

FIGS. 5A and 5B show residence time in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

As noted in the Background, many characterization techniques have been developed for various plasma-involved processes. However, plasma is not suitable for all semiconductor processes. For example, ionization should be avoided in the dry development of metal oxide resist (MOR), thus rendering plasma unsuited for the dry etch of MOR.

Meanwhile, optical emission spectroscopy (OES) is commonly used in the semiconductor industry to monitor or detect a plasma process. Conventional OES systems have limited sensitivity with weakly ionized gases or plasma-less processes. Therefore, there is a need for endpoint detection for a plasma-less process in a process chamber.

Techniques herein provide a system and a method that enable endpoint detection capability for metal oxide resist (MOR) dry development applications. An external plasma excitation coupler can be introduced at an exhaust of a plasma-less process chamber for MOR dry development, while an OES sensor analyzes the generated plasma. Additional process/algorithm can be implemented for high pressure operations.

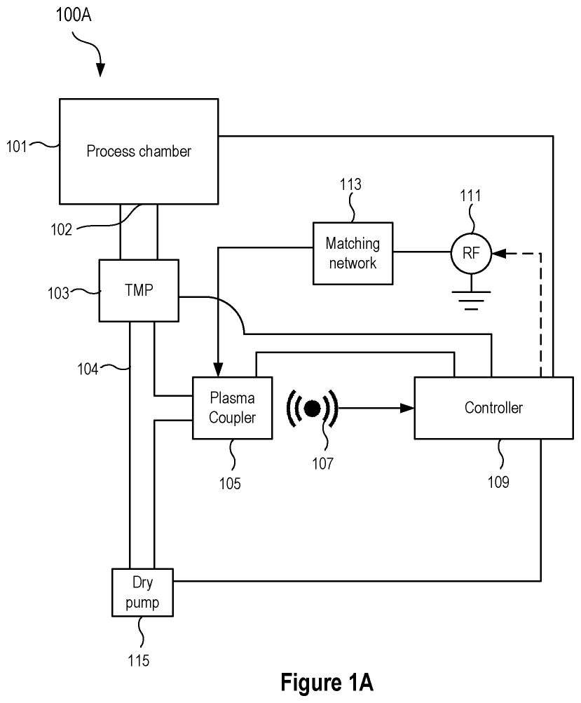

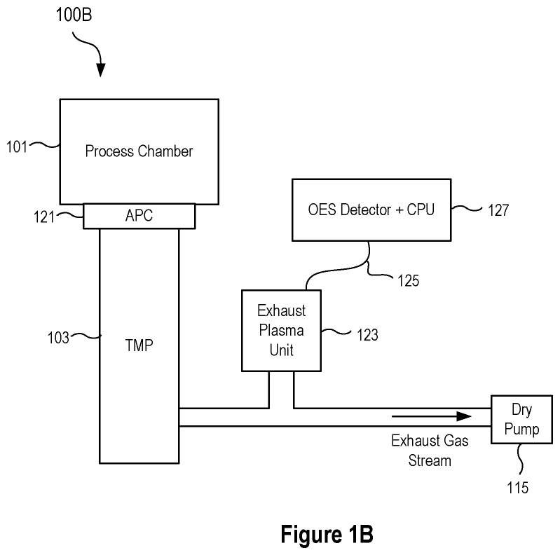

FIG. 1A shows a system 100A for endpoint detection in accordance with some embodiments of the present disclosure. As illustrated, the system 100A includes a process chamber 101 which can be configured to receive a wafer therein and perform a surface treatment on the wafer without plasma. The process chamber 101 includes an outlet 102 (also referred to as an exhaust) configured to output an exhaust gas of the surface treatment. In some embodiments, the system 100A can also include a pump such as a turbo molecular pump (TMP) 103 connected to the outlet 102 of the process chamber 101 and configured to transfer the exhaust gas out of the outlet 102.

In a non-limiting example, the surface treatment includes a dry development process, without plasma or with a remote plasma since the plasma density is very low in the process chamber for a remote plasma process, of a metal oxide resist (MOR) formed on the wafer. Techniques for MOR dry development are known to one skilled in the art and will not be elaborated on herein for simplicity purposes. As mentioned earlier, ionization should generally be avoided in dry development of MOR. Therefore, the process chamber 101 can be a plasma-less chamber.

The system 100A can further include a plasma coupler 105 configured to receive the exhaust gas and generate an exhaust plasma from the exhaust gas. The plasma coupler 105 can be a capacitively-coupled plasma processing apparatus, inductively-coupled plasma processing apparatus, microwave plasma processing apparatus, Radial Line Slot Antenna (RLSA™) microwave plasma processing apparatus, electron cyclotron resonance (ECR) plasma processing apparatus, or other types of processing systems or combination of systems. In this example, the plasma coupler 105 is preferably configured to enable inductively—or capacitively—coupled plasma excitation of the exhaust gas.

In some embodiments, a dry pump 115 can be used to direct the exhaust gas out of the TMP 103. The plasma coupler 105 may be positioned close to an outlet of the TMP 103 or close to a main line 104 connected to the outlet of the TMP 103 so that the plasma coupler 105 can receive most or all of the exhaust gas from the process chamber 101 via the TMP 103. Alternatively, the plasma coupler 105 can be placed anywhere on the main line 104. The plasma coupler 105 can receive at least 70% (e.g. 70%, 75%, 80%, 85%, 90%, 95%, 100% and any values therebetween) of the exhaust gas.

The system 100A can further include a detector 107 configured to analyze the exhaust plasma generated from the exhaust gas by the plasma coupler 105. For example, the detector 107 can be an optical emission spectrometer configured to detect at least one product and/or byproduct of the MOR dry development process that occurs in the process chamber 101. Using optical emission spectroscopy (OES) which can collect a wavelength range of for example 220-860 nm, one or more target wavelength signals can be monitored, including but not limited to 385 nm, 386 nm, and 387 nm and MOR byproduct related emission lines. In an embodiment, the optical emission spectrometer may have a wavelength range from 200 to 860 nm, to cover all wavelength ranges that are of potential interest.

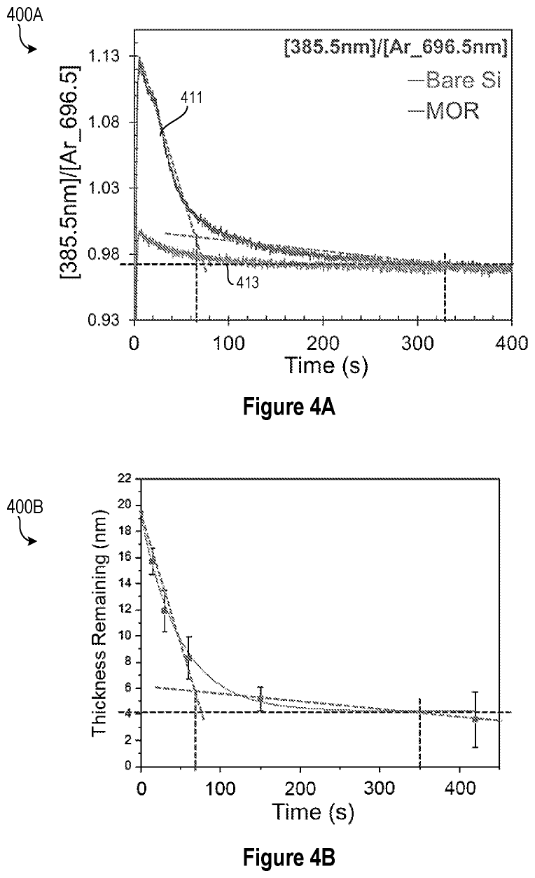

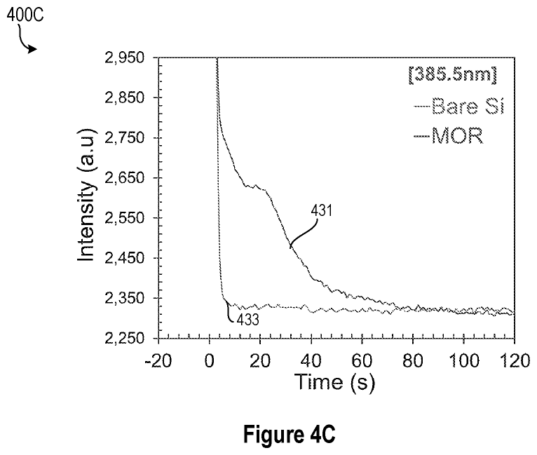

In the example of FIG. 4A, a graph 400A shows an OES trend by monitoring a wavelength of 386 nm for MOR 411 and bare silicon 413. In FIG. 4B, graph 400B is an etch rate trend. In FIG. 4C, a graph 400C shows an emission line 431 with a MOR wafer and an emission line 433 with a bare-Si wafer by monitoring the wavelength of 385.5 nm.

Referring back to FIG. 1A, the system 100A can optionally include a controller 109. Components of the system 100A can be connected to and controlled by the controller 109 that may optionally be connected to a corresponding memory storage unit and user interface (all not shown). Various processing operations can be executed via the user interface, and various processing recipes and operations can be stored in a storage unit. Accordingly, a given wafer can be processed within the process chamber 101 with various microfabrication techniques, especially plasma-less microfabrication techniques such as dry etch of MOR.

It will be recognized that the controller 109 may be coupled to one or more components of the system 100A to receive inputs from and provide outputs to the one or more components, including but not limited to the process chamber 101, the TMP 103, the plasma coupler 105, the detector 107, the dry pump 115, an RF generator 111 and/or a matching network 113. For example, the controller 109 can be configured to receive sensor data from the process chamber 101 and OES data from the detector 107. The controller 109 can also be configured to adjust knobs and control settings for the process chamber 101, the TMP 103, the plasma coupler 105, the detector 107, the dry pump 115, the RF generator 111 and/or the matching network 113. Of course the adjustments can be manually made as well.

The controller 109 can be implemented in a wide variety of manners. In one example, the controller 109 is a computer. In another example, the controller 109 includes one or more programmable integrated circuits that are programmed to provide the functionality described herein. For example, one or more processors (e.g. microprocessor, microcontroller, central processing unit (CPU), etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

FIG. 1B shows a system 100B for endpoint detection in accordance with some embodiments of the present disclosure. As illustrated, the system 100B can include an automatic pressure control (APC) valve 121 located between the process chamber 101 and the TMP 103. The APC valve 121 can be adjusted to reduce gas conductance and increase pressure in the process chamber 101. For instance, the dry pump 115 can be used to direct the exhaust gas out of the TMP 103. An exhaust plasma unit 123 may be configured to receive most or all of the exhaust gas (e.g. at least 70%, such as 70%, 75%, 80%, 85%, 90%, 95%, 100% and any values therebetween) from the process chamber 101 via the TMP 103. The exhaust plasma unit 123 can include a plasma coupler (e.g. 105) configured to generate an exhaust plasma from the received exhaust gas. A module 127 including an OES detector (e.g. 107) and CPU (e.g. 109) can be connected to the exhaust plasma unit 123 via a fiber optic cable 125.

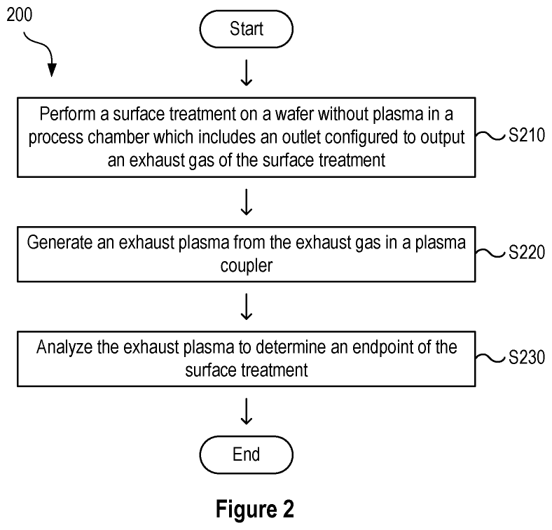

FIG. 2 shows a flow chart of a process 200 for endpoint detection in accordance with some embodiments of the present disclosure. At Step S210, a surface treatment is performed on a wafer in a process chamber which includes an outlet configured to output an exhaust gas of the surface treatment. At Step S220, an exhaust plasma is generated from the exhaust gas in a plasma coupler. At Step S230, the exhaust plasma is analyzed to determine an endpoint of the surface treatment.

Note that in the dry development of MOR, a relatively high vacuum pressure, for example of the order of 100 mTorr or more than 100 mTorr) is often necessary for the process chamber 101, which results in a long residence time compared to the time constant of the dry development chemical reaction. Additionally, chamber and exhaust pressures may change with the introduction of reactive precursors into the process chamber 101.

Particularly,

$${τ}_{r e s} = \frac{p {V}_{vol}}{{Q}_{flow}} ,$$

where τᵣₑₛ is a residence time. p is a pressure of the process chamber 101. Vᵥₒₗ is a volume of the process chamber 101. Q_{flow} is a gas flow rate. Q_{flow} is of the order of 100-5000 sccm (standard cubic centimeter per minute or atm cm³/min). τᵣₑₛ is of the order of seconds.

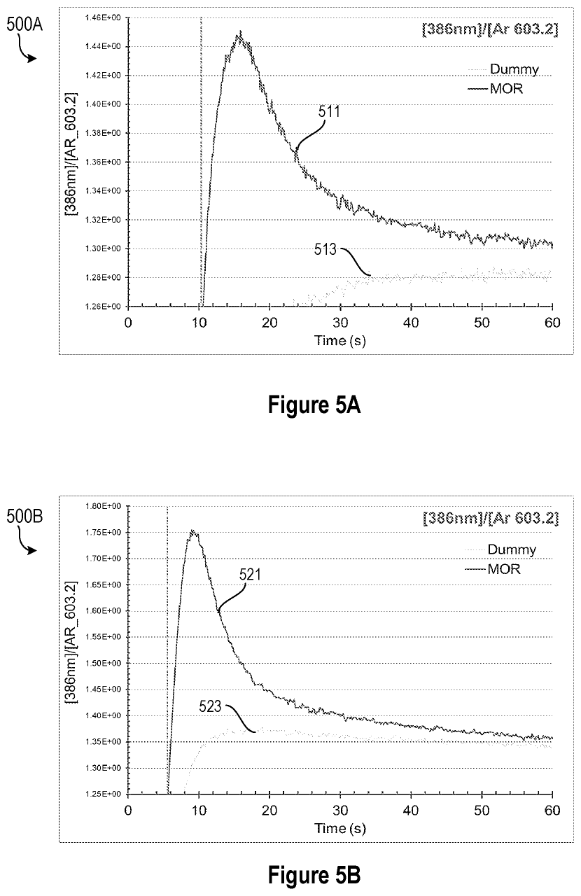

FIG. 5A shows an example of residence time. A line 511 represents a sample with MOR, and a line 513 represents a bare-Si wafer without MOR. As illustrated, the residence time for the line 511 is about 10 seconds.

To solve this problem, techniques herein provide a method to reduce the residence time under a relatively high vacuum pressure of 90-6000 mTorr, e.g. 90 mTorr, 100 mTorr, 120 mTorr, 140 mTorr, 160 mTorr, 180 mTorr, 200 mTorr, 250 mTorr, 300 mTorr, 1000 mTor, 5000 mTorr, 5500 mTorr, 6000 mTorr and any values therebetween.

According to some aspects of the present disclosure, a position of an automatic pressure control (APC) valve can be adjusted to reduce gas conductance and increase pressure in the process chamber. For instance, the APC valve can be adjusted to be 1-20% open, preferably 2-8% open, preferably 3-5% open, preferably 1-3%.

Then, a precursor gas can be introduced together with a carrier gas at a flow rate much higher than the best-known method (BKM) process recipe (e.g. 1.5 to 100 times higher) with the same flow ratio as the BKM process recipe. The precursor gas and the carrier gas can each include one or more gas species. In some embodiments, a process gas, which includes the precursor gas and the carrier gas, can be introduced into the process chamber initially at an overall flow rate that is 1.5 to 100 times (e.g. 1.5 times, 5 times, 10 times, 20 times, 30 times, 40 times, 50 times, 60 times, 70 times, 80 times, 90 times, 95 times, 100 times and any values therebetween) of a BKM overall flow rate of the BKM process recipe while keeping flow rate ratios of the gas species the same as the BKM process recipe. The process gas can be introduced by regular flow control system (FCS) units or separate high conductivity FCS units if necessary. In other embodiments, the precursor gas can be introduced together with the carrier gas at the flow rate much higher than the BKM process recipe, however with different flow ratios from the BKM process. For example, the carrier gas can be more concentrated than the precursor gas, or vice versa.

When a chamber pressure is close to a targeted process pressure (e.g. BKM recipe), the flow rates can be reduced, and high conductivity FCS units may be switched to regular FCSs if applicable. The APC valve can be adjusted to allow for a smooth pressure control until the targeted process pressure is reached. In other words, after the pressure in the process chamber reaches at least 60% (e.g. 60%, 80.0%, 82.5%, 85.0%, 87.5%, 90.0%, 92.5% 95.0%, 97.0%, 99.0% and any values therebetween) of the targeted process pressure (e.g. a recipe pressure according to the BKM process recipe), the overall flow rate of the process gas can be gradually (e.g. over a course of 1 second to 20 minutes, such as 1 second, 3 seconds, 5 seconds, 10 seconds, 30 seconds, 1 minute, 3 minutes, 5 minutes, 10 minutes, 20 minutes and any values therebetween) reduced to approximately the recipe overall flow rate. APC can be adjusted accordingly, so the pressure in the process chamber can be gradually (e.g. over a course of 1 second, 3 seconds to 20 minutes, such as 3 seconds, 5 seconds, 10 seconds, 30 seconds, 1 minute, 3 minutes, 5 minutes, 10 minutes, 20 minutes and any values therebetween) increased to the recipe pressure.

Additionally, actinometry tracing can be implemented for one or more emissions unique to a by-product composition. Residence time of gas molecules in the process chamber can be taken into account for determining an overetch time.

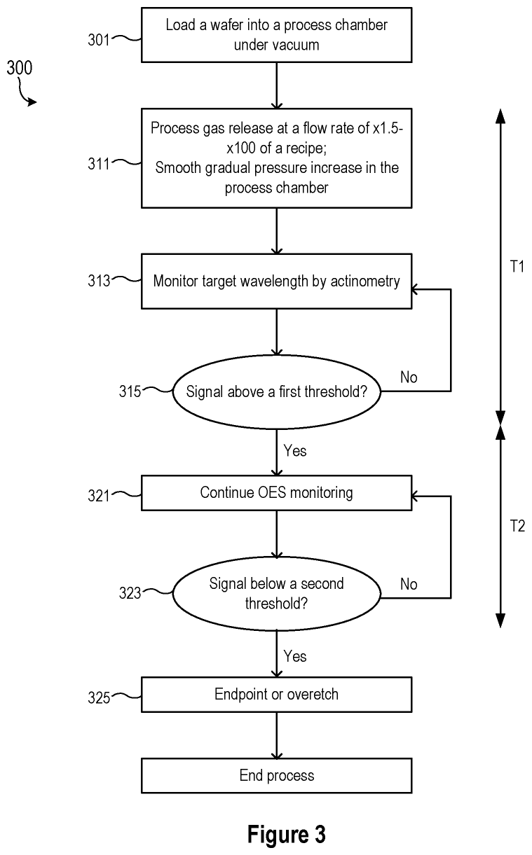

FIG. 3 shows a diagram of a process 300 for endpoint detection in dry development of MOR, in accordance with some embodiments of the present disclosure.

In Box 301, a wafer can be loaded into a process chamber (e.g. 101) under vacuum. Alternatively, the wafer may be loaded into the process chamber, and then the pressure in the process chamber is reduced to a vacuum pressure of no more than 100 mTorr, e.g. 100 mTorr, 75 mTorr, 50 mTorr, 25 mTorr, 10 mTorr, 5 mTorr, 1 mTorr, 0.5 mTorr, 0.1 mTorr and any values therebetween.

In some embodiments, a recipe for a surface treatment can be provided by a third party or by oneself. The recipe can be a best-known method (BKM) recipe or any recipe that is functional. The recipe can include information about gas species in a process gas including a precursor gas and a carrier gas. Such information can include, but not limited to, chemical formulae, individual flow rates, individual gas pressures, an overall flow rate, an overall gas pressure, flow rate ratios, temperature, and the like. In this example, the surface treatment includes a dry development of metal oxide resist (MOR) without plasma.

In Box 311, the process gas is released or introduced into the process chamber initially at an overall flow rate that is 1.5 to 100 times (e.g. 1.5 times, 5 times, 10 times, 20 times, 30 times, 40 times, 50 times, 60 times, 70 times, 80 times, 90 times, 95 times, 100 times and any values therebetween) of a recipe overall flow rate of the recipe with or without keeping flow rate ratios of the gas species the same as the recipe. Meanwhile, a pressure in the process chamber can be increased when the process gas is introduced into the process chamber. Such an increase can be a smooth gradual pressure increase in the process chamber by an advanced high-pressure valve. That is, the pressure in the process chamber can have a steady or even constant increase rate.

In Box 313, one or more target wavelengths can be monitored by actinometry. For example, signal for 386 nm can be monitored in OES as discussed above. Such monitoring can begin when the process gas is introduced into the process chamber.

In Ellipse 315, whether the signal is above a first threshold is determined. If no, processes in Box 311 and Box 313 are continued or repeated until the signal is above the first threshold. If or when the signal is above the first threshold, the process 300 proceeds to Box 321.

In some embodiments, the first threshold can correspond to an onset of the surface treatment on a surface of the wafer. The first threshold can be determined using knowledge of the dry development of the MOR or numerically based on a background level of emission or absorption. A first time, T1 can be recorded when the signal (e.g. 386 nm) exceeds the first threshold.

In Box 321, OES monitoring is continued, for instance as the surface treatment is continued. In some embodiments, the pressure is increased to and maintained at a target pressure (e.g. the pressure according to the BKM recipe). As a result, the surface treatment may eventually be performed according to the recipe.

In Ellipse 323, whether the signal is below a second threshold is determined. If no, the process is Box 321 is continued or repeated until the signal is below the second threshold. If or when the signal is below the second threshold, the process 300 proceeds to Box 325.

In some embodiments, the second threshold can correspond to an end of the surface treatment. The second threshold can be determined using knowledge of the dry development of the MOR or numerically based on a background level of emission or absorption. A second time, T2 can be recorded when the signal (e.g. 386 nm) falls below the second threshold.

In Box 325, an endpoint time of MOR dry development can be determined based on the first time T1 and/or the second time T2. If no overetch time is specified in the process recipe, the process ends. If an overetch time is required for the process, the process continues until the overetch time is reached, then the process ends. For example, the end of T2 (i.e. when the signal falls below the second threshold) can be interpreted as the endpoint of the MOR dry development. T2 can be interpreted as a duration of surface reaction. A sum of T1 and T2 can be interpreted as a duration of the dry etch operation. Accordingly, an overetch time can be obtained by subtracting the sum of T1 and T2 from an overall operation time.

FIG. 5B shows a residence time using techniques herein, such as the process 300 in FIG. 3. A line 521 represents a sample with MOR, and a line 523 represents a bare-Si wafer without MOR. As illustrated, the residence time for the line 511 is about 5 seconds, representing a reduction of about 50% compared to the residence time of FIG. 5A. In other words, residence time can be reduced by an initially increased flow rate as discussed in Box 311.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of endpoint detection, the method comprising:
performing a surface treatment on a wafer without plasma in a process chamber which includes an outlet configured to output an exhaust gas of the surface treatment;
generating an exhaust plasma from the exhaust gas in a plasma coupler; and
analyzing the exhaust plasma to determine an endpoint of the surface treatment.

2. The method of claim 1, wherein performing the surface treatment comprises:
executing a dry development process, without plasma, of a metal oxide resist formed on the wafer.

3. The method of claim 1, wherein analyzing the exhaust plasma comprises:
detecting a byproduct of the surface treatment using optical emission spectroscopy.

4. The method of claim 1, further comprising:
providing a recipe for the surface treatment, the recipe including gas species in a process gas; and
introducing the process gas into the process chamber initially at an overall flow rate that is 1.5 to 100 times of an overall flow rate of the recipe while keeping flow rate ratios of the gas species the same as the recipe.

5. The method of claim 4, further comprising:
increasing a pressure in the process chamber while introducing the process gas into the process chamber; and
after the pressure in the process chamber reaches at least 60% of a recipe pressure of the recipe, gradually reducing the overall flow rate to the overall flow rate of the recipe.

6. The method of claim 5, further comprising:
increasing the pressure in the process chamber to the recipe pressure; and
maintaining the pressure at the recipe pressure so that the surface treatment is performed according to the recipe.

7. The method of claim 6, further comprising:
loading the wafer into the process chamber under vacuum before initially introducing the process gas into the process chamber.

8. The method of claim 5, further comprising:
introducing the process gas initially into the process chamber using a first flow control system; and
after the pressure in the process chamber reaches at least 60% of the recipe pressure, introducing the process gas into the process chamber using a second flow control system,
wherein the first flow control system has a higher conductivity than the second flow control system.

9. The method of claim 5, wherein:
the overall flow rate is gradually reduced to the overall flow rate of the recipe after the pressure reaches at least 90% of the recipe pressure.

10. The method of claim 4, wherein:
the overall flow rate is initially 5 to 95 times of the overall flow rate of the recipe.

11. The method of claim 1, wherein:
performing the surface treatment comprises executing a dry development process, without plasma, of a metal oxide resist formed on the wafer, and
analyzing the exhaust plasma comprises monitoring a byproduct of the dry development process by monitoring at least one target wavelength signal using optical emission spectroscopy.

12. The method of claim 11, further comprising:
recording a first time when the at least one target wavelength signal exceeds a first threshold corresponding to an onset of the surface treatment; and
recording a second time when at least one the target wavelength signal falls below a second threshold corresponding to an end of the surface treatment.

13. The method of claim 12, further comprising:
determining an over-etch time of the dry development process based on the first time and the second time.

14. The method of claim 12, further comprising:
determining a duration of the dry development process based on the first time and the second time.

15. A system, comprising:
a process chamber configured to receive a wafer and perform a surface treatment on the wafer without plasma, the process chamber including an outlet configured to output an exhaust gas of the surface treatment;
a plasma coupler configured to receive the exhaust gas and generate an exhaust plasma therefrom; and
a detector configured to receive and analyze the exhaust plasma.

16. The system of claim 15, further comprising:
a turbo molecular pump configured to transfer the exhaust gas out of the outlet of the process chamber.

17. The system of claim 15, wherein:
the detector includes an optical emission spectrometer.

18. The system of claim 15, wherein:
the surface treatment includes a dry development of metal oxide resist.

19. The system of claim 15, further comprising:
a controller configured to determine an endpoint of the surface treatment based on analysis of the detector.

20. The system of claim 15, wherein:
the plasma coupler is located outside and downstream relative to the process chamber, and
the detector is located outside the process chamber and downstream relative to the plasma coupler.
